(19) United States
(12) Patent Application Publication
(10) Pub. No.: US 2002/0010754 A1
(43) Pub. Date: Jan. 24, 2002

(54) Electric power metering package

(76) Inventor: Keith R. Brown, Oklahoma City, OK (US)

Correspondence Address: ROBERT V. RACUNAS, Fish & Richardson P.C., 601 Thirteenth Street, NW, Washington, DC, 20005, US

(21) Appl. No.: 09/828,170

(22) Filed: Apr. 9, 2001

Related U.S. Application Data
(60) Provisional application No. 60/195,199, filed on Apr. 7, 2000.

(51) Int. Cl. G06F 15/16; G01R 11/56; G06F 17/00; G01R 21/133

(52) U.S. Cl. 709/217

(57) ABSTRACT

Remote access to a non-Internet enabled software application for displaying utility data is enabled by providing a host system capable of communicating with a client system over an Internet connection. The host system has an Internet-ready framework, and the non-Internet enabled software application is embedded in the Internet-ready framework locally on the host system. Selective access is permitted to the host system by the client system to access and run the non-Internet enabled software application to display utility data.

### CROSS-REFERENCE TO RELATED APPLICATIONS

This application is a continuation application and claims priority to U.S. application Ser. No. 60/195,199, filed on Apr. 7, 2000, which is incorporated herein by reference.

### TECHNICAL FIELD

This invention relates to remote operation of data analysis software, particularly software to track and analyze utility consumption data.

### BACKGROUND

In the utility industry, data acquisition and analysis systems are used to collect information about a customer's utility usage. Data about utility usage can be analyzed to determine a utility consumer's pattern of use over a time period, including the customer's peak usage, which may be known as a “load profile.” Load profiles may be created from a time series of utility consumption data. Load profiles may be determined for different time periods, such as, for example, a day, a week, or a year. Use of electricity, water, gas, and other utilities is generally greatest during daylight and business hours, but may also depend on other factors, such as weather or a customer's production schedule.

Since the supply of utilities generally does not depend significantly on such factors as the time of day, the day of the week, or the weather, the supply generally exhibits smaller periodic fluctuations than the demand does, and the price of a utility is generally determined by demand. Therefore, accurately predicting a customer's demand for a utility facilitates prediction of a customer's utility costs and creates a more efficient market for the utility.

A customer's future utility demand may be predicted by analyzing the customer's historical load profiles of utility usage, including load profiles detailing usage over different time scales. Historical load profiles may be used to predict a customer's pattern of utility usage on several different timescales, and the price of the utility may be adjusted according. For example, electricity may be more expensive during the summer when air conditioning is used, as opposed to the winter, and during daylight hours when businesses are operating, as opposed to nighttime hours, or during a company's peak production time, as opposed to a time of low production. Therefore, the collection of utility consumption data and the analysis of the load profiles of utility customers, both as individuals and as groups, is useful in determining a price and creating an efficient market for the utility.

### SUMMARY

In one general aspect, remote access to a non-Internet enabled software application for displaying utility data is enabled by providing a host system capable of communicating with a client system over an Internet connection. The host system has an Internet-ready framework, and the non-Internet enabled software application is embedded in the Internet-ready framework locally on the host system. Selective access is permitted to the host system by the client system to access and run the non-Internet enabled software application to display utility data.

Implementations may include one or more of the following features. For example, utility data may be acquired automatically from one or more remote terminal units and utility data may include power use data. A user of the client system may be prompted to enter a password, and access to the host system may be permitted only if the password entered by the user is identical to a predetermined password. Selective access the host system may be given to a user of the client system by providing permitting selected access to selected data stored on the host system. Running the non-Internet enabled software application may include plotting the utility data in a graphical format. Utility data may include a utility consumption time series.

These and other features may be used in the client-server model, as described, or in some other network connected computer environment. These features may be implemented using, for example, a method or a process, a device, an apparatus or a system, or software stored on a computer-readable medium.

Other features and advantages will become apparent from the description, the drawings, and the claims.

### DESCRIPTION OF DRAWINGS

FIG. 1 is a schematic diagram of a computer network.

FIG. 2 is a screen shot of a login screen to grant access to a software resource of the computer network of claim 1.

FIG. 3 is a screen shot of an Internet-enabled host frame and icons representing non-Internet-enabled software applications that may be run in the Internet-enabled host frame using the computer network of claim 1.

FIG. 4 is a screen shot of a utility load profile displayed with non-Internet-enabled software being run through an Internet-enabled host frame using the computer network of claim 1.

FIG. 5 is a screen shot of a utility load profile displayed with non-Internet-enabled software being run through an Internet-enabled host frame using the computer network of claim 1.

FIG. 6 is a schematic diagram of a computer system included in the computer network of claim 1.

Like reference symbols in the various drawings indicate like elements.

### DETAILED DESCRIPTION

Data acquisition and analysis systems, including those used for utility consumption applications, often are implemented and managed for customer specific applications. For example, a utility company may collect data about a customer's utility usage from remote terminal units (RTUs) located at a customer's site. The utility company then may analyze the data using software designed specially for the utility company's needs or designed specially to analyze the data from the RTUs. Specialty acquisition and analysis software systems must be implemented, maintained, and updated by qualified personnel. Considerable investment in creating and maintaining such a system is generally required, such that it is often impractical for small organizations, including small utilities and customers of utilities to implement and use such a system.

Many businesses and small utility companies have not previously felt an urgent need to track in detail their own, or their customers', utility usage. When a fixed price is charged for consumption of a utility unit, utility consumers and suppliers may not need to track utility usage on short-term time scales. If a supplier bills a consumer monthly, and the price of the utility does not vary during a billing cycle, it may be sufficient for both the supplier and the consumer to track utility consumption on a monthly basis. Monthly, or less frequent, changes to the price of a utility are common in regulated utility markets.

When the price of a utility varies on a short-term timescale (e.g, in deregulated utility markets), it is desirable to track utility consumption on a correspondingly short timescale. Since utility demand is generally greatest during the daylight hours of business days, but utility suppliers generally prefer to operate at a constant output rate, suppliers may charge different prices for utility consumption during peak and low demand periods. A supplier may want to be able to anticipate fluctuating demand in order to allocate resources to meet the demand and also to be able to set demand-dependent rates in advance of the anticipated demand. Similarly, a consumer may want to be able to anticipate demand in order to forecast utility expenses, or to alter a short-term utility usage pattern to reduce expenses, while maintaining a long-term total consumption level. Thus, having information about a customer's utility consumption on a fine timescale (measured every hour, or every few minutes) is useful both to the utility supplier and to the utility consumer, as it permits them to negotiate a price for the utility in an efficient market.

Advanced data acquisition and analysis systems to track and analyze utility consumption on a fine timescale traditionally have been developed and implemented in-house by organizations (e.g., large utility companies) for their own internal use. Successful development and implementation of such a system generally requires staffing by qualified personnel and financial resources to update the system as technology changes. Smaller and less resourceful organizations that might use such systems often have failed to implement such systems, either because the task is of a lower priority than the organization's core business concerns or because the organization does not have the human or capital resources to implement the system. Because of economic pressures due primarily to deregulation of utility markets, however, it has become increasingly important for smaller suppliers and consumers of utilities, in addition to large suppliers, to implement sophisticated data acquisition and analysis systems in order to compete in the marketplace.

As an alternative to in-house development and maintenance of a sophisticated data acquisition and analysis system, which may be impractical for small suppliers and consumers, an organization may use an outsource service company that can provide an appropriate data acquisition and analysis system for the organization. The outsource service company can collect and analyze data about many different organizations' utility consumption and then provide access to the raw and processed data to the individual organizations it serves.

Outsource data acquisition and analysis service may be provided through an Internet-enabled centralized host system that receives utility usage data from meters and RTUs. Customers, utility suppliers, and other users of the service then may use the Internet to access the data and software to analyze, format, and display the data relevant to their needs. Sophisticated data acquisition and analysis software traditionally has been developed for particular client-specific applications, however, and often is not adaptable to the needs of multiple users. Few powerful Internet specific systems exist, and even fewer provide the capability of existing 32-bit Microsoft Windows® applications. One approach to implementing existing sophisticated analysis software on an Internet platform is to rewrite the software as an Internet specific application in Java® or Microsoft ActiveX®. However, rewriting software is costly and may introduce flaws in the programs, and rewritten software often has less power and utility than original versions of the software.

To retain all the functionality of a sophisticated, powerful non-Internet-enabled data acquisition and analysis system, while providing Internet access to the system, an Internet-enabled framework may be used to provide access to the system. For example, by using a framework consisting of Microsoft's Windows NT® Terminal Server, Windows 2000 Advanced Server™, or Citrix's MetaFrame®, an organization can efficiently and cost-effectively implement a stand alone 32-bit Windows software application that allows users to interact with the software over the Internet. Access to such a system allows an organization to use pre-existing sophisticated data acquisition and analysis software without having to develop or maintain the software.

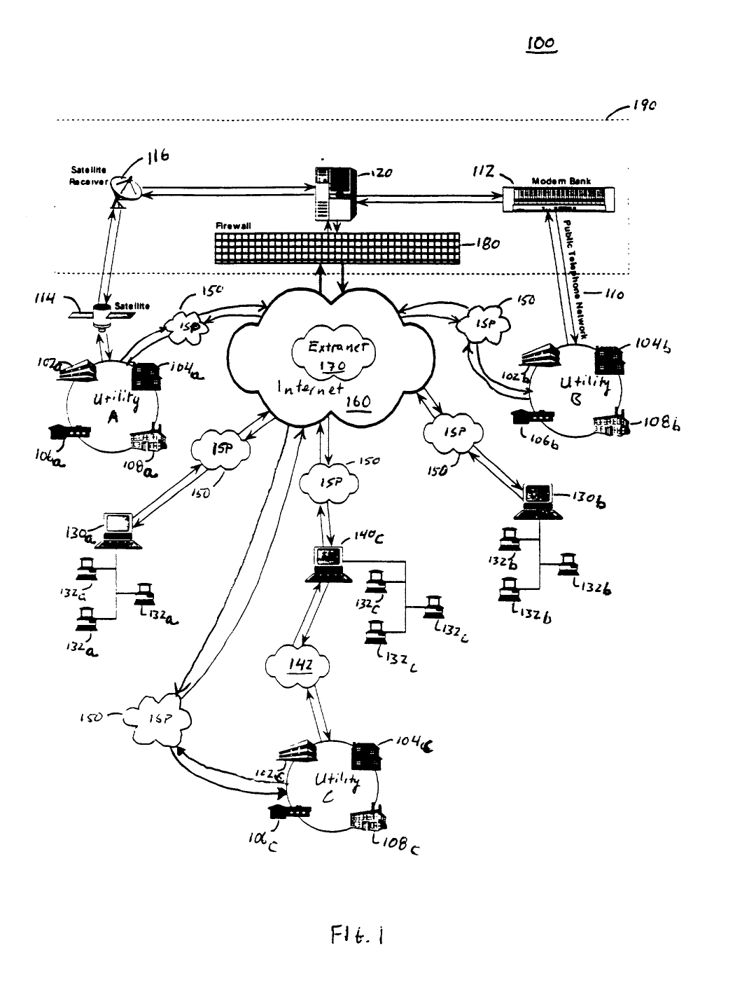

Referring to FIG. 1, a utility data collection and analysis system 100 may include a host 190 connected to clients that may access the host and transmit information back and forth between the client and the host. Host 190 may include equipment for receiving information from the clients, such as, for example, a modem bank 112 for receiving information transmitted over telephone or cable lines 110, or a satellite receiver 116 for receiving information over a wireless transmission link. Host 190 may include one or more server computers for receiving data from modem bank 112 or satellite receiver 116, storing the data, and for running software for processing the data, including sophisticated non-Internet enabled analysis software.

A variety of different data types may be uploaded from clients, including from suppliers and consumers, to host 190. RTUs may be installed at the consumer's site to monitor utility consumption by a consumer, such as an office building 102, a production facility 104, a residence 106, or an apartment complex 108. RTUs may upload data from the customer's site directly to the host 190 through wired telephone links 110, via a satellite 114 over a wireless link, or over the Internet by sending the data to an Internet Service Provider (ISP) 150 that connects to the Internet 160 to send the data to the host 190. RTUs may also indirectly upload data from a customer to host 190, by first sending the data over a data transmission link 142 to the utility supplier's host computer 140 where it may be stored and/or processed before uploading it to host 190.

Different utility suppliers may serve different customers or utility consumers. For example, utility A may supply customers 102a, 104a, 106a, and 108a, and utility B may supply customers 102b, 104b, 106b, and 108b. Different utilities also may have their own client computers (e.g., 130a, 130b, 140c) for transmitting data to and from host 190 through the Internet 160. An individual utility also may run its own software applications 132a, 132b, 132c on its client computers 130a, 130b, 130c for processing data pertaining to the individual utility or to the customers of the utility.

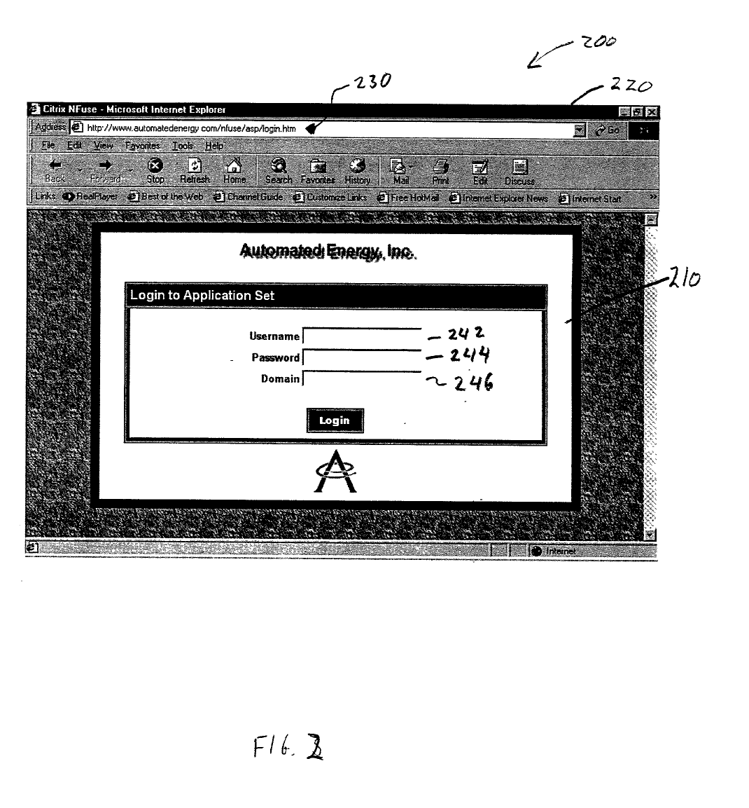

Referring to FIG. 2, users may log in to host 190 through a login screen 210 provided by an Internet-enabled interface 200 of extranet 170. A user may use an Internet browser 220 (e.g., Microsoft's Internet Explorer or Netscape's Navigator) running on a client computer 130, 140 to access a login screen 210 by entering the uniform resource locator (URL) 230 of the login screen address in the browser interface. The user then may enter information, such as, for example, a predetermined username 242, a password 244, and a domain name 246 in order to gain access to the software applications and systems provided by host 190 through extranet 170.

Referring again to FIG. 1, users, including utility suppliers (e.g. utility A, utility B, or utility C) and utility consumers (e.g., 102, 104, 106, 108), may login to host 190, which is protected by a firewall 180, through an Internet-enabled extranet 170 provided by the host. A user may be given selective access to data stored on host 190, such that the user is given access only to its own data, and the confidentiality of other users' data stored on host 190 is maintained. For example, utility A may be given selective access only to data concerning customers of utility A (e.g., 102a, 104a, 106a, and 108a), while utility B is given access only to data concerning customers of utility B (e.g., 102b, 104b, 106b, and 108b). Individual customers of a utility (e.g., 102a, 104a, 106a, 108a, 102b, 104b, 106b, 108b, 102c, 104c, 106c, and 108c) may be given selective access only to their own data, but not to data of other customers of the same utility or to data of the customers of other utilities. Selected data may be downloaded to the user from host 190 through an ISP 150 to the user's client computer 130.

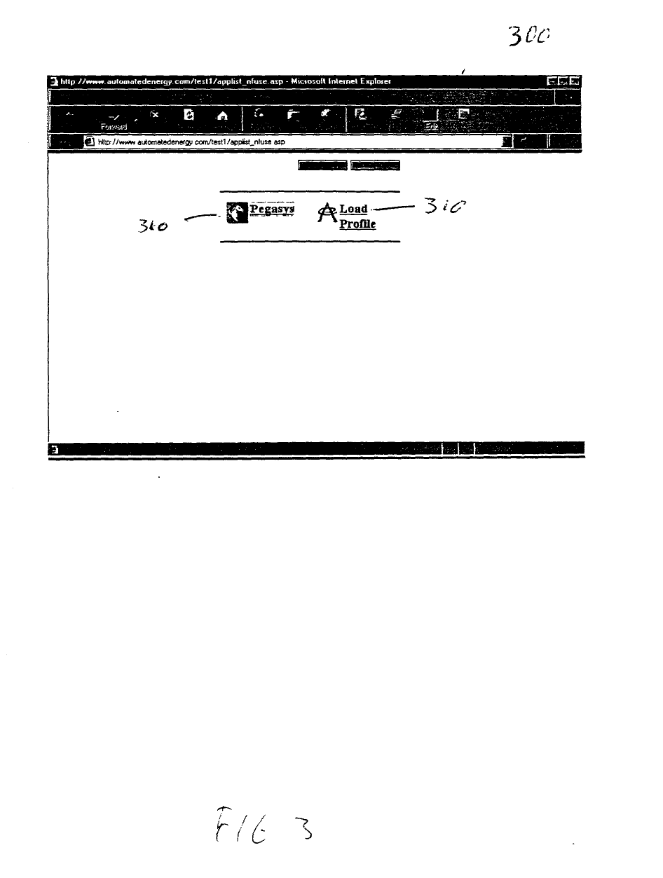

Referring to FIG. 3, once a user has successfully entered a username, password, and domain name to gain access to the extranet 170, an Internet-enable framework 300 for providing access to non-Internet enabled software applications is displayed to the user. Icons 310 representing different software applications may be displayed to the user through Internet-enabled framework 300 of the extranet 170.

Internet-enabled framework 300 may be a framework, such as, for example, Citrix MetaFrame™ or Citrix Nfuse™, which permit access to a non-Internet enabled application running on the host's server. The non-Internet enabled software application runs entirely on the host's server, and only the user interface is transmitted to users. Thus, the application need not be modified from its standalone architecture, and users can interface with the application through the Internet-enabled framework 300. The Internet-enabled framework enables the transmission of the user interface of the software application, including keystrokes and mouse movements, over the Internet-enabled framework 300 to the user. Standard network protocols, such as, example, TCP/IP, PPP, IPX, SPX, and NetBEUI, as well as network connections, such as, for example, asynchronous, dial-up, ISDN, Frame Relay, and ATM may be used to transfer the user interface. Because only the user interface of the application is transmitted over the framework 300, the application may reside and run entirely on the server 120. Therefore, the application need not be specifically written, or rewritten, to interface with a remote user through an Internet framework. Instead, an Internet-ready framework may be used to provide a user interface through the Internet to a non-Internet enabled software application or system.

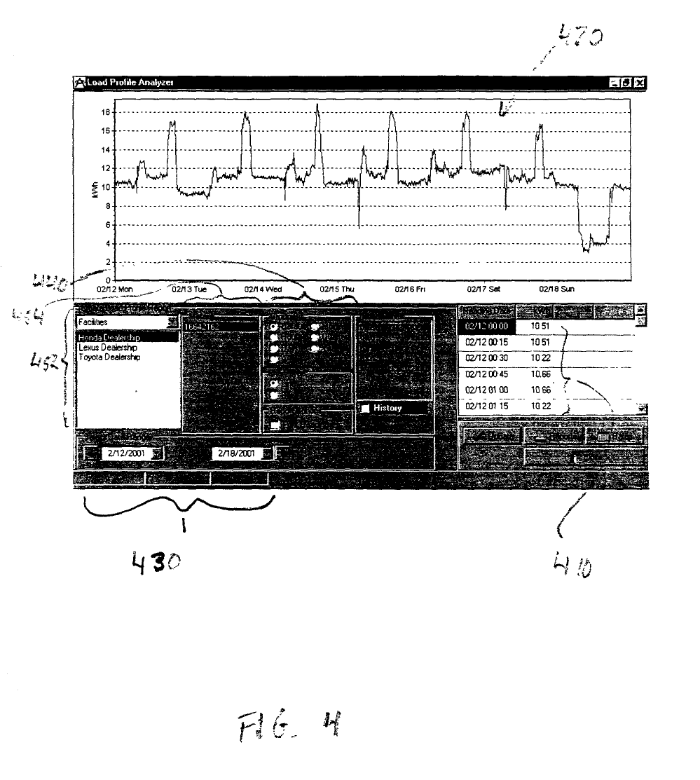

Referring to FIG. 4, a software application stored on host 190, and accessible through extranet 170, is capable of storing energy usage data retrieved from one or more RTUs. The energy usage data include a time series 410 recorded by one or more RTUs of energy consumed during regular intervals. The time series is displayed graphically in the form of a load profile 420. Different time periods of the time series may be selected for graphical display by entering beginning and ending times for the display through the user interface 430, and the format and density of points in the time series plot may be chosen from several predetermined formats 440. Load profiles may be created from data recorded by one or more RTUs. For example, load profiles may be created for different facilities 452, or for the data from different RTUs at a facility 454 according to the user's choice. Additionally, cummulative load profiles may be created from data derived from multiple RTUs. For example, load profiles tracking the utility consumption of a group of a customer's facilities, of a group of customers, of a geographic region, or of a group of sites served by a particular utility plant may be created and displayed.

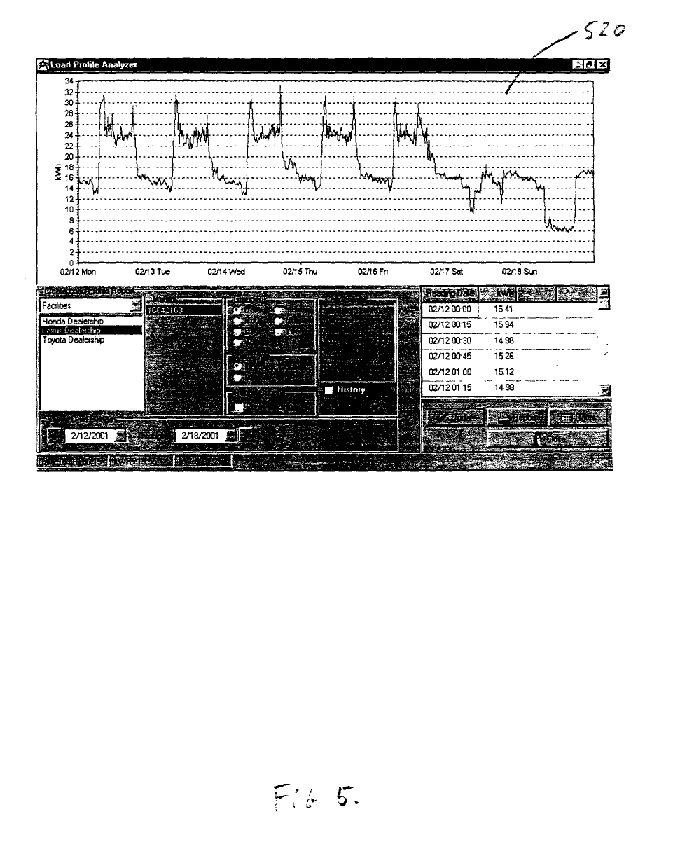

The load profile 420 displayed in FIG. 4 shows periodic maxima in the energy consumption at a Honda® Dealership occuring approximately between the hours of 4:00 and 8:00 pm, Monday through Saturday. Referring to FIG. 5, a load profile 520 for energy consumption at a Lexus® Dealership shows periodic maxima in energy consumption approximately between the hours of 7:00 am and 6:30 pm, Monday through Friday. If energy demand on a utility supplier is greatest, and therefore most expensive, during the middle of the day, for example, between 9:00 am and 3:00 pm, the Honda dealership may be able to negotiate an advantageous rate for the cost of its energy, because its periods of peak energy consumption are between 4:00 and 8:00 pm. Without the information contained in the time series data 410 and the load profile 420, the Honda dealership would generally have to purchase energy from a supplier based on its total energy consumption for a month, or based on its peak energy consumption during a period of time, and would not be able to benefit from the fact that its peak consumption occurs during low demand hours for the utility supplier. By analyzing its load profile using software stored on server 120 of host 190 through an extranet connection 170, the Honda dealership is able to demonstrate that its peak energy use does not occur between 9:00 am and 3:00 pm, which would generally benefit the dealership when negotiating a price for energy with the supplier. Of course, viewing the load profile is also valuable for the utility supplier, since it can adjust its rates for a particular customer based on the customer's usage pattern, and therefore can offer a competitive rate with respect to other utility suppliers with which it competes.

The load profile of the Lexus dealership shows that even though it uses most energy between the hours of 7:00 am and 6:30 pm, the dealership uses energy at an especially high rate approximately for an hour around 7:30 am and for a half hour around 5:30 pm. Thus, the information contained in the load profile for the Lexus dealership may be used to demonstrate that spikes in energy consumption generally do not occur during midday hours between 9:00 am and 3:00 pm.

Load profiles for several different customers may be analyzed, so that a group of customers may “package” themselves together in order to negotiate a package rate for the group. If some customers in the group use energy mostly at night and others generally consume energy during the day, their collective consumption may not vary greatly, which may be attractive for an energy supplier that wants to match a relatively constant supply to relatively constant demand. A utility supplier could offer price incentives to a group of customers who purchase the utility for the entire group, since the consumption of a large group of consumers generally fluctuates less than the consumption of an individual consumer. Additionally, the utility supplier could offer incentives to encourage a group to use energy at a steady rate, with relatively low fluctuations.

Since sophisticated software systems and applications generally are not available in standalone Internet-ready format, access to a non-Internet enabled software system through an Internet-enabled framework may provide customers and suppliers with access to software applications for receiving, storing, analyzing, and displaying utility data. For example, utility consumption data may be collected and uploaded by RTUs to host 190, where the data are stored. The host may verify on a daily basis that all scheduled meter readings have occurred and may notify a customer of any possible meter failures. The host may run a software application to analyze the data, create load profiles, and display the analyzed data and load profiles to a user. One example of such an application is American Innovations' AIMetering System®. The Internet-ready framework may display the output and the user interface of the software application to the user through an Internet-ready framework, even though the software application is a standalone application and is itself not Internet-enabled.

The techniques, methods, and systems described here may find applicability in any computing or processing environment. Various implementations of the systems and techniques described here may be realized in digital electronic circuitry, or in computer hardware, firmware, software, or in combinations thereof. A system or other apparatus that uses one or more of the techniques and methods described here may be implemented as a computer-readable storage medium, configured with a computer program, where the storage medium so configured causes a computer system to operate on input and/or generate output in a specific and predefined manner. Such a computer system may include one or more programmable processors that receive data and instructions from, and transmit data and instructions to, a data storage system, and suitable input and output devices. Each computer program may be implemented in a high-level procedural or object-oriented programming language, or in assembly or machine language if desired; and in any case, the language may be a compiled or interpreted language. Suitable processors include, by way of example, both general and special purpose microprocessors.

Generally, a processor will receive instructions and data from a read-only memory and/or a random access memory. Storage devices suitable for tangibly embodying computer instructions and data include all forms of non-volatile memory, including semiconductor memory devices, such as EPROM, EEPROM, and flash memory devices; magnetic disks such as internal hard disks and removable disks; magneto-optical disks; and CD-ROM disks.

These elements also can be found in a desktop or workstation computer as well as other computers suitable for executing computer programs implementing the methods described here, which can be used in conjunction with any content viewing or manipulation software, or any other software capable of displaying portions of a larger body of content. Any of the foregoing may be supplemented by, or implemented in, specially designed ASICs (application specific integrated circuits).

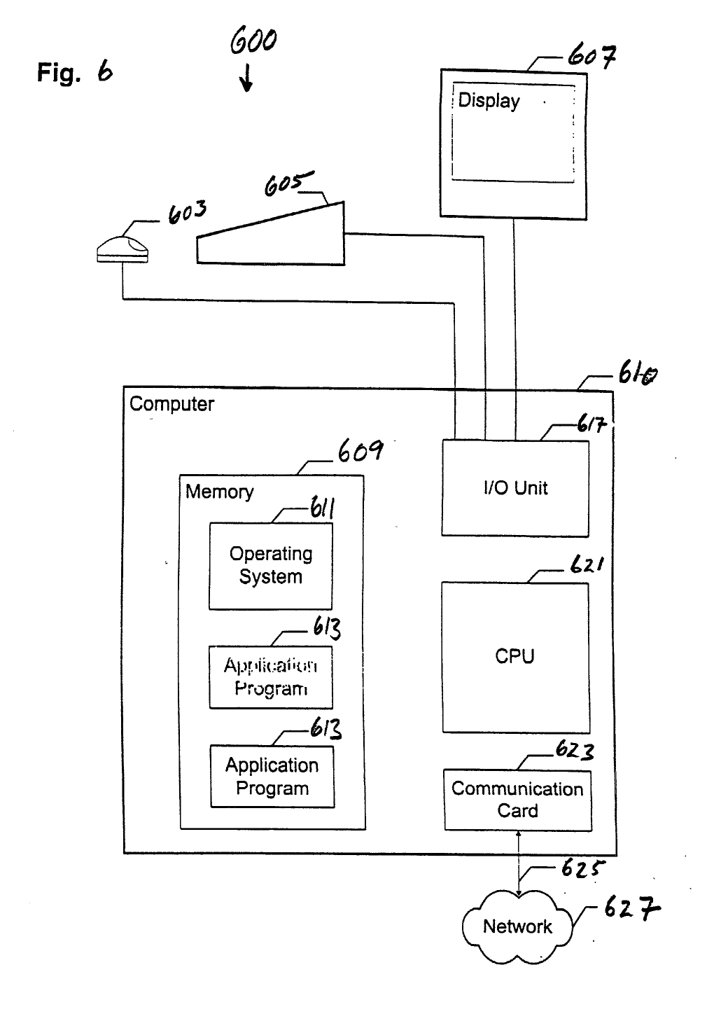

Referring to FIG. 6, a computer system 600 represents a hardware setup for executing software that allows a user to perform tasks such as sending, storing, viewing, editing, analyzing, retrieving, and downloading data, including utility consumption data. The computer system 600 of FIG. 6 may also be programmed with computer-readable instructions to enable data to be perceived as stored, viewed, edited, retrieve, downloaded, and otherwise manipulated.

The computer system includes various input/output (I/O) devices (mouse 603, keyboard 605, display 607) and one or more general purpose computers 610 having a central processor unit (CPU) 621, an I/O unit 617 and a memory 609 that stores data and various programs such as an operating system 611, and one or more application programs 613. The computer system 600 preferably also includes some sort of communications card or device 623 (for example, a satellite receiver, a modem, or network adapter) for exchanging data with a network 627 via a communications link 625 (for example, a telephone line, a wireless link).

A number of implementations have been described. Nevertheless, it will be understood that various modifications may be made. Accordingly, other implementations are within the scope of the following claims.

What is claimed is:

1. A method of providing remote access to a non-Internet enabled software application for displaying utility data, the method comprising:
providing a host system capable of communicating with a client system over an Internet connection, the host system having an Internet-ready framework;
embedding the non-Internet enabled software application in the Internet-ready framework locally on the host system; and
permitting selective access to the host system by the client system to access and run the non-Internet enabled software application to display utility data.

2. The method of claim 1 wherein the utility data are acquired automatically from one or more remote terminal units.

3. The method of claim 1 wherein the utility data include power use data.

4. The method of claim 1 further comprising:
prompting a user of the client system to enter a password; and
permitting access to the host system only if the password entered by the user is identical to a predetermined password.

5. The method of claim 1 wherein:
permitting selective access to the host system includes permitting selected access to selected data stored on the host system; and
running the non-Internet enabled software application includes plotting the utility data in a graphical format.

6. The method of claim 5 wherein the utility data include a utility consumption time series.

7. A computer program, residing on a computer-readable storage medium for providing remote access to a non-Internet enabled software application for displaying utility data, the computer program comprising instructions to:
provide selective access to a host system capable of communicating with a client system over an Internet connection, the host system having an Internet-ready framework;
embed the non-Internet enabled software application in the Internet-ready framework locally on the host system; and
permit a client system with access to the host system to run the non-Internet enabled software application to display utility data.

8. The computer program of claim 7 wherein the utility data are acquired automatically from one or more remote terminal units.

9. The computer program of claim 7 wherein the utility data include power use data.

10. The computer program of claim 7 further comprising instructions for:
prompting a user of the client system to enter a password; and
permitting access to the host system only if the password entered by the user is identical to a predetermined password.

11. The computer program of claim 7 wherein:
permitting selective access to the host system includes permitting selected access to selected data stored on the host system; and
running the non-Internet enabled software application includes plotting the utility data in a graphical format.

12. The computer program of claim 11 wherein the utility data include a utility consumption time series.

13. A computer system for providing remote access to a non-Internet enabled software application for displaying utility data, the system comprising:
a host system capable of communicating with a client system over an Internet connection;
an Internet-ready framework running on the host system embedding the non-Internet enabled software application; and
a controller that permits selective access to the host system by the client system to access and run the non-Internet enabled software application to display utility data.

14. The system of claim 13 wherein the utility data are acquired automatically from one or more remote terminal units.

15. The system of claim 13 wherein the utility data include power use data.

16. The system of claim 13 wherein the controller:
prompts a user of the client system to enter a password; and
permits access to the host system only if the password entered by the user is identical to a predetermined password.

17. The system of claim 13 wherein the controller permits selective access to the host system by permitting selected access to selected data stored on the host system, and running the non-Internet enabled software a application includes plotting the utility data in a graphical format.

18. The system of claim 17 wherein the utility data include a utility consumption time series.
